(19) United States
(12) Patent Application Publication
(10) Pub. No.: US 2025/0212329 A1
(43) Pub. Date: Jun. 26, 2025

(54) ELECTRONIC BOARD

(71) Applicant: Lenovo (Beijing) Limited, Beijing (CN)

(72) Inventors: Seiji Yamasaki, Kanagawa (JP); Ryosuke Ito, Kanagawa (JP); Hua Wang, Beijing (CN)

(73) Assignee: Lenovo (Beijing) Limited, Beijing (CN)

(21) Appl. No.: 18/943,326

(22) Filed: Nov. 11, 2024

(30) Foreign Application Priority Data
Dec. 22, 2023 (CN) 2023117856831

(51) Int. Cl. H05K 1/11; H05K 3/12

(52) U.S. Cl. CPC H05K 1/111; H05K 3/125; H05K 2201/10159

(57) ABSTRACT

An electronic board includes: a support substrate; a memory and a processor connected to the support substrate by solder; and two or more storage elements that store the ID of the memory. Each of the two or more storage elements includes: a first electrically conductive pad placed on the support substrate; and a second electrically conductive pad placed on the support substrate, being spaced away from the first pad by a gap. At least one of the two or more storage elements contains solder and has a connection layer that electrically connects the first pad and the second pad.

### CROSS-REFERENCE TO RELATED APPLICATIONS

This application claims priority to Chinese Patent Application No. 2023117856831 filed on Dec. 22, 2023, the contents of which are hereby incorporated herein by reference in their entirety.

### BACKGROUND OF THE INVENTION

### Field of the Invention

The present invention relates to an electronic board.

### Description of the Related Art

If a user wishes to purchase a personal computer (PC), the user can visit the website of a company that sells PCs, and order a PC on the website. When the user orders a PC, the user can specify the specifications of a central processing unit (CPU), and memories and the like installed in the PC. In an existing general manufacturing process, a factory uses surface mount technology (SMT) to manufacture motherboards for individual combinations of various types of CPUs and memories. The manufactured motherboards are stored in the factory. Japanese Unexamined Patent Application Publication No. 2023-134353 discloses a motherboard manufactured using the SMT.

After a user places an order for a PC, the inventory of motherboards is checked at the factory according to the order details. If a motherboard with a CPU and memories specified by the user is not in stock, then a motherboard with those particular CPU and memories is manufactured at the factory.

As described above, in an existing general manufacturing process, factories need to stock a large number of motherboards to accommodate combinations of various types of CPUs and memories. This results in high cost for storage of motherboards. In addition, if a motherboard with a CPU and memories specified by a user is not in stock and therefore has to be manufactured, the factory may not necessarily be able to quickly start manufacturing the motherboard.

On the other hand, in order to reduce the amount of inventory of motherboards in a factory, the manufacturing process described below is used. The factory manufactures motherboards with memories mounted but no CPU mounted, and stores the motherboards. In the process of manufacturing the motherboards, a manufacturing line using SMT (SMT line) is used. After a user places an order for a PC, the factory selects a motherboard equipped with memories specified by the user, and then mounts, on the motherboard, a CPU specified by the user. In a process for mounting CPUs on motherboards, a manufacturing line different from the SMT line is used.

The manufacturing process described above reduces the amount of motherboard inventory, as compared with a general manufacturing process. Further, a factory can mount CPUs on motherboards by a manufacturing line different from the SMT line, so that the manufacture of motherboards in the SMT line is not affected.

### SUMMARY OF THE INVENTION

In order to further reduce the quantity of motherboards in stock at factories, a manufacturing process is being considered in which a CPU and memories are mounted on a motherboard after a user places an order for a PC. The following will describe the manufacturing process. A factory manufactures motherboards with no CPU and memories mounted thereon on an SMT line, and stores the motherboards. After a user places an order for a PC, the factory mounts a CPU and memories specified by the user on a motherboard by a manufacturing line different from the SMT line.

A CPU uses firmware based on the specifications of memories mounted on a motherboard. The CPU selects firmware according to memory IDs set on the motherboard. In the manufacturing process described above, an operator at a factory is required to manually set the IDs according to the types of memories mounted on a motherboard.

Embodiments of the present invention provide an electronic board that can reduce the amount of work required for setting a memory ID.

A first aspect of the present invention is an electronic board including: a support substrate; a memory and a processor connected to the support substrate by solder; and two or more storage elements that store an ID of the memory, wherein each of the two or more storage elements has a first electrically conductive pad placed on the support substrate and a second electrically conductive pad placed on the support substrate with a gap with respect to the first pad, and at least one of the two or more storage elements contains solder and has a connection layer that electrically connects the first pad and the second pad.

In a second aspect of the present invention, the electronic board may include a first insulating layer placed on the first pad except a first area thereof where the first pad and a part of the connection layer overlap, and a second insulating layer placed on the second pad except a second area thereof where the second pad and a part of the connection layer overlap.

In a third aspect of the present invention, the first insulating layer and the second insulating layer may not be placed in the gap.

In a fourth aspect of the present invention, a width of the gap may be 0.15 mm or more and 0.175 mm or less.

According to the above-described aspects of the present invention, the electronic board can reduce the amount of work required for setting a memory ID.

### BRIEF DESCRIPTION OF THE DRAWINGS

FIG. 1 is a diagram illustrating an example of a hardware configuration of an electronic apparatus according to an embodiment.

FIG. 2 is a diagram illustrating a configuration example of an ID storage unit included in the electronic apparatus according to the embodiment.

FIG. 3 is a diagram illustrating a configuration example of a storage element included in the electronic apparatus according to the embodiment.

FIG. 4 is a diagram illustrating an example of the manufacturing process of the storage element and a main memory included in the electronic apparatus according to the embodiment.

FIG. 5 is a diagram illustrating the example of the manufacturing process of the storage element and the main memory included in the electronic apparatus according to the embodiment.

FIG. 6 is a diagram illustrating the example of the manufacturing process of the storage element and the main memory included in the electronic apparatus according to the embodiment.

FIG. 7 is a diagram illustrating the example of the manufacturing process of the storage element and the main memory included in the electronic apparatus according to the embodiment.

FIG. 8 is a diagram illustrating the example of the manufacturing process of the storage element and the main memory included in the electronic apparatus according to the embodiment.

### DETAILED DESCRIPTION OF THE INVENTION

Embodiments of the present invention will be described below with reference to the accompanying drawings.

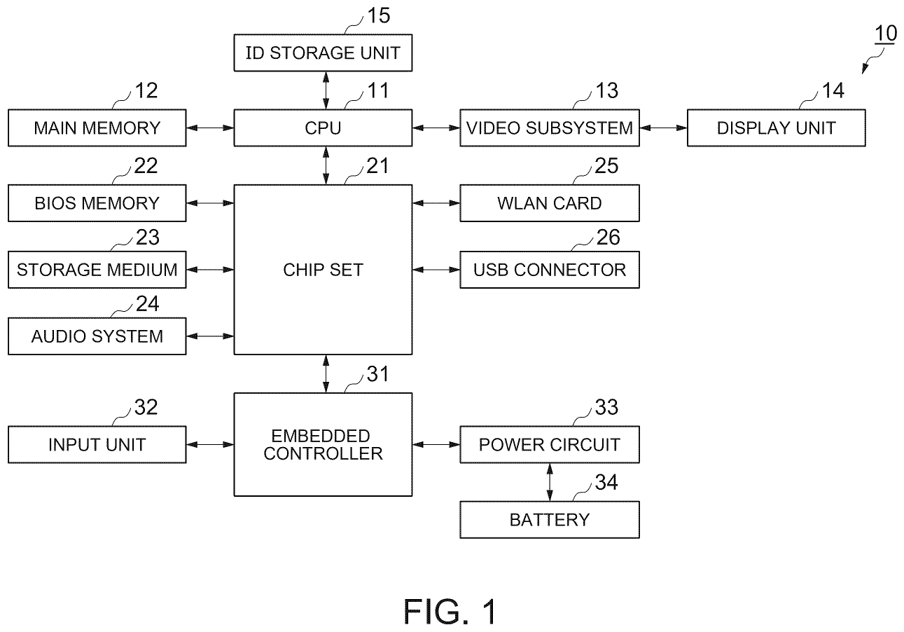

Referring to FIG. 1, an example of the hardware configuration of an electronic apparatus 10 according to an embodiment will be described. FIG. 1 is a block diagram illustrating an example of the hardware configuration of the electronic apparatus 10.

The electronic apparatus 10 includes a CPU 11, a main memory 12, a video subsystem 13, a display unit 14, an ID storage unit 15, a chip set 21, a BIOS memory 22, a storage medium 23, an audio system 24, a WLAN card 25, a USB connector 26, an embedded controller 31, an input unit 32, a power circuit 33, and a battery 34.

The CPU 11 executes various types of arithmetic processing under program control, and controls the entire electronic apparatus 10. For example, the CPU 11 performs processing based on an operating system (OS) and a basic input/output system (BIOS) programs. The CPU 11 is an example of a processor.

The main memory 12 is a writable memory used as an area into which the CPU 11 reads an execution program, or as a work area into which data to be processed by the execution program is written. The main memory 12 is composed of, for example, a plurality of dynamic random access memory (DRAM) chips. The execution program includes an OS, various drivers for performing hardware operation of peripherals, various services/utilities, application programs, and the like.

The video subsystem 13 is a subsystem for implementing functions related to image display, and includes a video controller. The video controller processes drawing commands from the CPU 11, writes the processed drawing information to a video memory, reads the drawing information from the video memory, and outputs the drawing information as drawing data (display data) to the display unit 14.

The display unit 14 is, for example, a liquid crystal display or an organic EL display, and shows display screens based on drawing data (display data) output from the video subsystem 13.

The ID storage unit 15 stores IDs for identifying the main memory 12. Hereinafter, the ID of the main memory 12 will be described as the memory ID.

The chip set 21 includes controllers such as a universal serial bus (USB), a serial ATA (AT Attachment), a serial peripheral interface (SPI) bus, a peripheral component interconnect (PCI) bus, a PCI-Express bus, and a low pin count (LPC) bus, and a plurality of devices are connected thereto. The plurality of devices include, for example, the BIOS memory 22, the storage medium 23, the audio system 24, the WLAN card 25, the USB connector 26, and the embedded controller 31, which will be described later.

The BIOS memory 22 is composed of an electrically rewritable nonvolatile memory such as, for example, an electrically erasable programmable read only memory (EEPROM) or a flash ROM. The BIOS memory 22 stores system firmware and the like for controlling a BIOS, the embedded controller 31, and the like. The BIOS memory 22 is an example of a sub memory.

The storage medium 23 includes a hard disk drive (HDD), a solid state drive (SSD), and the like. The storage medium 23 stores, for example, an OS, various drivers, various services/utilities, application programs, and various data.

The audio system 24 has a microphone and a speaker (not illustrated) connected thereto, and records, plays, and outputs sound data. The microphone and the speaker are, for example, built in the electronic apparatus 10.

The wireless local area network (WLAN) card 25 connects to a network via a wireless LAN to perform data communication. For example, upon receipt of data through the network, the WLAN card 25 generates an event trigger indicating that the data has been received. The USB connector 26 is a connector for connecting peripherals that use USB.

The input unit 32 collectively represents input devices (input equipment) included in the electronic apparatus 10. The input unit 32 includes a keyboard, a mouse, and the like. The input unit 32 outputs input information entered by a user operation to the embedded controller 31.

The power circuit 33 includes, for example, a DC/DC converter, a charge/discharge unit, an AC/DC adapter, and the like. For example, the power circuit 33 converts a DC voltage supplied from an external power source such as an AC adapter (not illustrated) or the battery 34 into a plurality of voltages required to operate the electronic apparatus 10. The power circuit 33 also supplies power to each part of the electronic apparatus 10 under the control of the embedded controller 31.

The battery 34 is, for example, a secondary battery such as a lithium ion battery. When power is supplied from an external power source to the electronic apparatus 10, the battery 34 is charged via the power circuit 33. When power is not supplied from an external power source to the electronic apparatus 10, the battery 34 outputs stored power via the power circuit 33 as operating power for the electronic apparatus 10.

The embedded controller 31 is a one-chip microcomputer that monitors and controls various devices (peripherals, sensors, and the like) regardless of the system state of the electronic apparatus 10. The embedded controller 31 includes a CPU, a ROM, a RAM, multi-channel A/D input terminals, a D/A output terminal, a timer, and digital input/output terminals, which are not illustrated. The input unit 32, the power circuit 33, and the like are connected to the digital input/output terminals of the embedded controller 31, and the embedded controller 31 controls the operations thereof. Further, the embedded controller 31 controls changes or the like in the clock frequency of the CPU 11 via the chip set 21.

The electronic apparatus 10 may be a portable device such as a clamshell type personal computer, a tablet terminal, or a smartphone, and a display device may be integrally attached to the chassis of the electronic apparatus 10. Alternatively, the apparatus body and the display device may be separate, as in a desktop type personal computer. The electronic apparatus according to the present embodiment is applicable to general apparatuses equipped with CPUs.

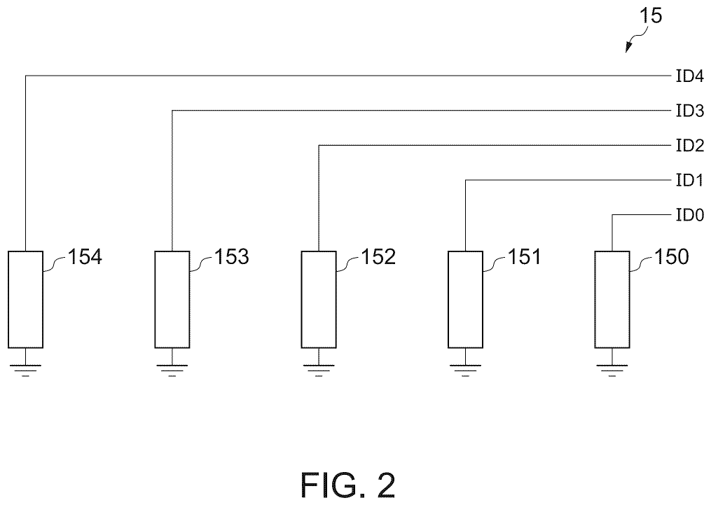

Referring to FIG. 2, an example of the configuration of the ID storage unit 15 will be described. FIG. 2 is a block diagram illustrating the example of the configuration of the ID storage unit 15.

The ID storage unit 15 includes two or more storage elements. In the example illustrated in FIG. 2, the ID storage unit 15 includes a storage element 150, a storage element 151, a storage element 152, a storage element 153, and a storage element 154. Although the five storage elements are illustrated in FIG. 2, the number of the storage elements is not limited to five. The number of the storage elements included in the ID storage unit 15 is, for example, two or more and five or less.

For example, a memory ID is 5-bit data. The memory ID includes bit ID0, bit ID1, bit ID2, bit ID3, and bit ID4. The storage elements 150 to 154 store bits ID0 to ID4, respectively. The storage elements 150 to 154 are electrically connected to the CPU 11.

The state of each of the storage elements 150 to 154 is set to either an open state (high resistance state) or a closed state (low resistance state). One of these two states corresponds to the value of each bit.

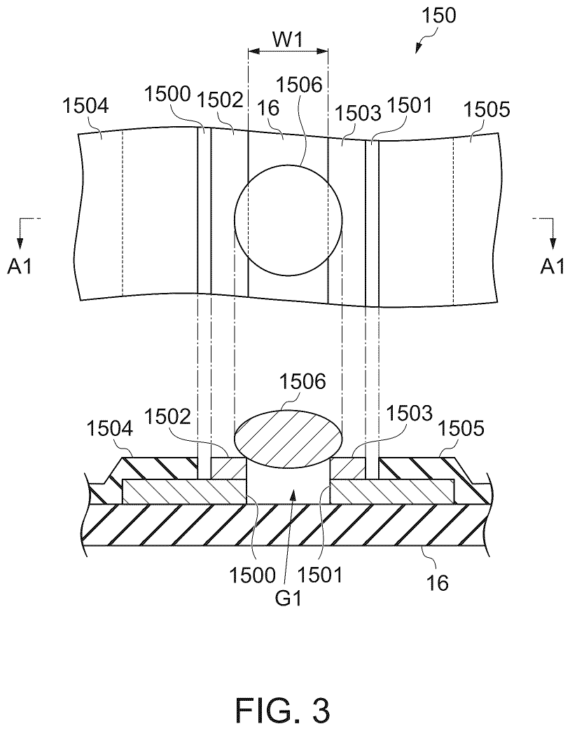

Referring to FIG. 3, an example of the configuration of the storage elements included in the ID storage unit 15 will be described. FIG. 3 includes a plan view and a sectional view illustrating an example of the configuration of the storage element 150. The configurations of the storage elements 151 to 154 are the same as the configuration of the storage element 150, so that the description of the configurations of the storage elements 151 to 154 will be omitted.

The upper drawing in FIG. 3 is the plan view of the storage element 150. The lower drawing in FIG. 3 is the sectional view of the storage element 150 taken along line A1-A1.

The storage element 150 is placed on a flat support substrate 16. The CPU 11, the main memory 12, and the like illustrated in FIG. 1 are also placed on the support substrate 16, but are omitted in FIG. 3. The support substrate 16 constitutes a motherboard and supports the CPU 11, the main memory 12, the ID storage unit 15, and the like.

The storage element 150 includes a first pad 1500, a second pad 1501, a first connection pad 1502, a second connection pad 1503, a first insulating layer 1504, a second insulating layer 1505, and a connection layer 1506.

The first pad 1500 and the second pad 1501 are placed on a surface of the support substrate 16. The first pad 1500 and the second pad 1501 are formed of an electrically conductive material. The first pad 1500 and the second pad 1501 are placed with a gap G1 provided therebetween. One of the first pad 1500 and the second pad 1501 is electrically connected with the CPU 11 via wiring not illustrated in FIG. 3. The other of the first pad 1500 and the second pad 1501 is electrically connected with a ground terminal, which is provided on the support substrate 16, via wiring not illustrated in FIG. 3.

The first connection pad 1502 is placed on a surface of the first pad 1500. The first connection pad 1502 electrically connects the first pad 1500 and the connection layer 1506. The second connection pad 1503 is placed on a surface of the second pad 1501. The second connection pad 1503 electrically connects the second pad 1501 and the connection layer 1506. The first connection pad 1502 and the second connection pad 1503 are formed of solder.

The first insulating layer 1504 covers a part of the surface of the first pad 1500 and the surface of the support substrate 16. The second insulating layer 1505 covers a part of the surface of the second pad 1501 and the surface of the support substrate 16. The first insulating layer 1504 and the second insulating layer 1505 are formed of an insulating material. The first insulating layer 1504 and the second insulating layer 1505 protect the surfaces of the first pad 1500, the second pad 1501, and the support substrate 16.

The first pad 1500 overlaps with the first connection pad 1502 in a first area of the surface of the first pad 1500, and overlaps with a part of the connection layer 1506 in the first area. The first insulating layer 1504 is not placed on the first area, but placed on the surface of the first pad 1500 except the first area. The second pad 1501 overlaps with the second connection pad 1503 in a second area of the surface of the second pad 1501, and overlaps with a part of the connection layer 1506 in the second area. The second insulating layer 1505 is not placed on the second area, but placed on the surface of the second pad 1501 except the second area.

In the example illustrated in FIG. 3, the first insulating layer 1504 and the second insulating layer 1505 are illustrated as insulating layers that are different from each other; however, the first insulating layer 1504 and the second insulating layer 1505 may alternatively be the same insulating layers connected in an area not illustrated in FIG. 3.

The connection layer 1506 is placed on the surface of the first connection pad 1502 and the surface of the second connection pad 1503. The connection layer 1506 is formed of solder. When the connection layer 1506 is viewed in a direction perpendicular to the surface of the support substrate 16, the shape of the connection layer 1506 is, for example, circular. The connection layer 1506 electrically connects the first connection pad 1502 and the second connection pad 1503.

When the state of the storage element 150 is set to the closed state, the connection layer 1506 is placed. When the state of the storage element 150 is set to the open state, the connection layer 1506 is not placed. At least one of the storage elements 150 to 154 has the connection layer 1506.

It is difficult to form solder on an insulating layer. No insulating layer is placed in the gap G1 between the first pad 1500 and the second pad 1501 in order to secure electrical connection between the connection layer 1506 and the first connection pad 1502 and to secure electrical connection between the connection layer 1506 and the second connection pad 1503.

A width W1 of the gap G1 is, for example, 6 mil (0.15 mm) or more and 7 mil (0.175 mm) or less. One mil is 0.0254 mm. The width W1 indicates the distance between the first pad 1500 and the second pad 1501 in a direction parallel to the surface of the support substrate 16. The diameter of the connection layer 1506 in a direction parallel to the surface of the support substrate 16 is, for example, 15 mil (0.39 mm).

In a general manufacturing process, a resistance element is placed instead of the connection layer 1506. When a resistance element is placed, an insulating layer is placed in the gap G1 between the first pad 1500 and the second pad 1501. In such a case, the width W1 of the gap G1 is, for example, 8 mil (0.20 mm). In one or more embodiments of the present invention, the connection layer 1506 is placed instead of a resistance element, thus making it possible to reduce the width W1 of the gap G1, as compared with the case where a resistance element is placed.

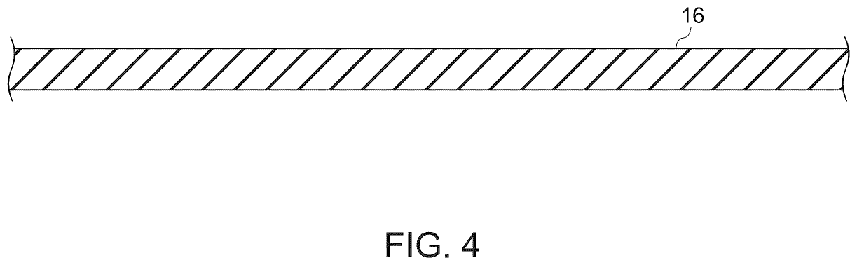

Referring to FIG. 4 to FIG. 8, the manufacturing method of the storage element 150 will be described. FIG. 4 to FIG. 8 are sectional views illustrating an example of the manufacturing process of the storage element 150 and the main memory 12. The storage elements 151 to 154 are formed at the same time when the storage element 150 is formed. The manufacturing method of the storage elements 151 to 154 is the same as the manufacturing method of the storage element 150, so that the description of the manufacturing method of the storage elements 151 to 154 will be omitted.

First, the support substrate 16 is prepared, as illustrated in FIG. 4.

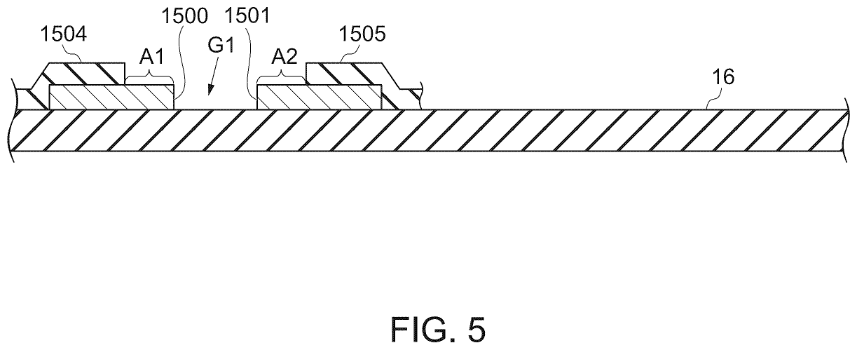

Subsequently, as illustrated in FIG. 5, the first pad 1500 and the second pad 1501 are formed on the surface of the support substrate 16. The first pad 1500 and the second pad 1501 are spaced apart from each other by the gap G1 provided therebetween. Further, the first insulating layer 1504 is formed on the surface of the first pad 1500 except a first area A1 of the first pad 1500 and on the surface of the support substrate 16. Further, the second insulating layer 1505 is formed on the surface of the second pad 1501 except a second area A2 of the second pad 1501 and on the surface of the support substrate 16.

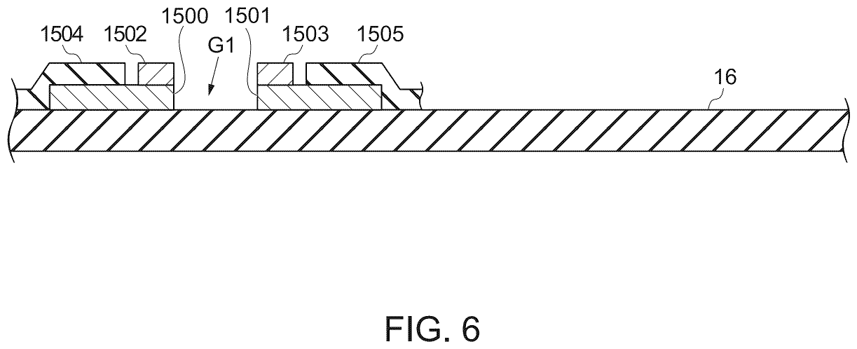

Subsequently, as illustrated in FIG. 6, the first connection pad 1502 is formed on the first area A1 illustrated in FIG. 5, and the second connection pad 1503 is formed on the second area A2 illustrated in FIG. 5.

A factory uses an SMT line to carry out the steps illustrated in FIG. 4 to FIG. 6. The factory stores motherboards having the structure illustrated in FIG. 6.

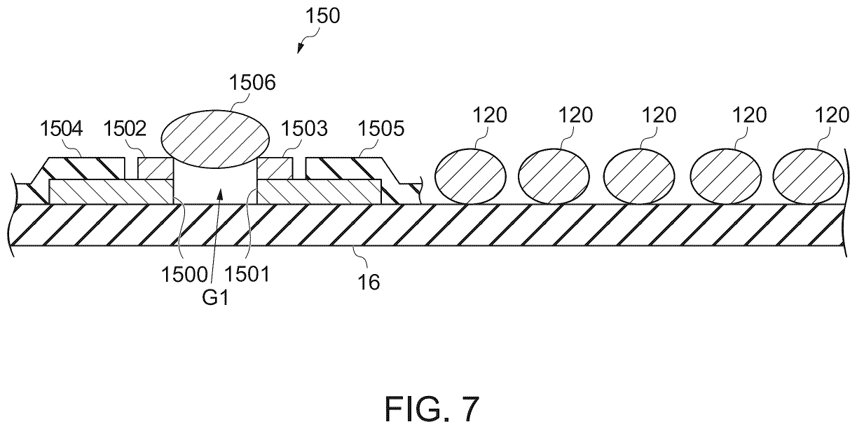

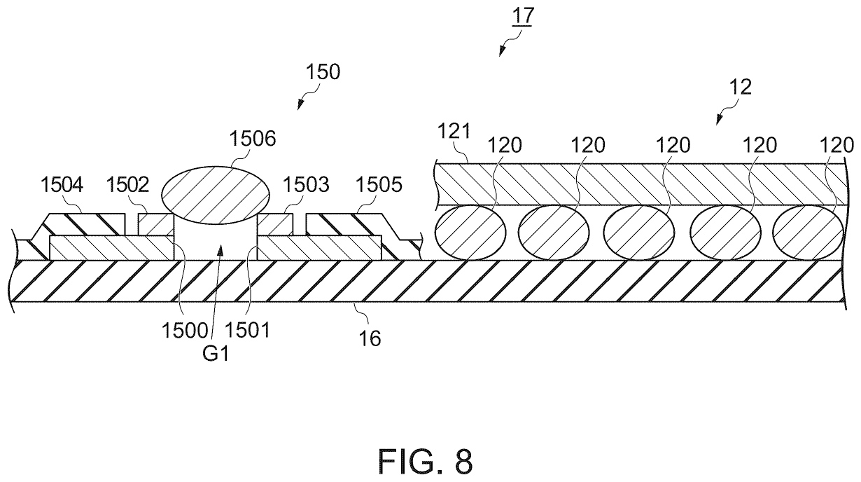

After a user specifies the specifications of particular CPU 11 and main memory 12, the factory uses a manufacturing line, which is different from the SMT line, to carry out the steps illustrated in FIG. 7 and FIG. 8.

As illustrated in FIG. 7, the connection layer 1506 is formed on the surface of the first connection pad 1502 and the surface of the second connection pad 1503. Further, connection layers 120 are formed on the surface of the support substrate 16. The connection layers 120 are formed of solder. The connection layer 1506 and the connection layers 120 are simultaneously formed by jet solder printing. At this time, a connection layer similar to the connection layers 120 is formed on the surface of the support substrate 16 on which the CPU 11 is formed. The connection layers 120 are connected to the wiring on the support substrate 16.

Subsequently, as illustrated in FIG. 8, a substrate 121 of the main memory 12 is placed on the connection layers 120. The substrate 121 is connected to the support substrate 16 through the connection layers 120. In other words, the substrate 121 is electrically connected to the wiring on the support substrate 16 via the connection layers 120. Similarly, the substrate of the CPU 11 is placed on the connection layers formed on the support substrate 16. The substrate of the CPU 11 is connected to the support substrate 16 through the connection layers. In other words, the substrate of the CPU 11 is electrically connected to the wiring on the support substrate 16 via the connection layers.

The steps illustrated in FIG. 4 to FIG. 8 are carried out to manufacture an electronic board 17 illustrated in FIG. 8.

As described above, the electronic board 17 includes the support substrate 16, the main memory 12 and the CPU 11 connected to the support substrate 16 by solder, and the two or more storage elements 150 to 154 that store memory IDs. Each of the two or more storage elements 150 to 154 includes the electrically conductive first pad 1500 and the electrically conductive second pad 1501. The first pad 1500 is placed on the support substrate 16. The second pad 1501 is placed on the support substrate 16 and is spaced apart from the first pad 1500 by the gap G1. At least one of the two or more storage elements 150 to 154 contains solder, and has the connection layer 1506 that electrically connects the first pad 1500 and the second pad 1501.

The connection layer 1506 is formed by the jet solder printing at the same time when the connection layer of the main memory 12 and the connection layer of the CPU 11 are formed. A user does not have to manually set a memory ID, thus making it possible to reduce the amount of work required for setting a memory ID. Further, there is no need to install additional equipment to a factory to form the connection layer 1506.

The electronic board 17 includes the first insulating layer 1504 and the second insulating layer 1505. The first insulating layer 1504 is placed on the first pad 1500 except the first area A1 where the first pad 1500 and a part of the connection layer 1506 overlap. The second insulating layer 1505 is placed on the second pad 1501 except the second area A2 where the second pad 1501 and a part of the connection layer 1506 overlap.

The first insulating layer 1504 and the second insulating layer 1505 are not placed in the gap G1. This makes it possible to reduce the width W1 of the gap G1.

The width W1 of the gap G1 may be 6 mil (0.15 mm) or more and 7 mil (0.175 mm) or less. If the width W1 may be smaller than 6 mil, then the risk of electric short-circuiting between the first pad 1500 and the second pad 1501 increases. If the width W1 is larger than 7 mil, then it becomes difficult to form the connection layer 1506 that connects the first pad 1500 and the second pad 1501. Setting the range of the width W1 as described above makes it possible to avoid the short-circuiting between the first pad 1500 and the second pad 1501 and also to easily form the connection layer 1506.

The above has described in detail one or more embodiments of the present invention with reference to the accompanying drawings. However, a specific configuration is not limited to that of the above-described embodiment, and design changes and the like are included within a scope not departing from the gist of the present invention.

### DESCRIPTION OF SYMBOLS

10 electronic apparatus
11 CPU
12 main memory
13 video subsystem
14 display unit
15 ID storage unit
16 support substrate
17 electronic board
21 chip set
22 BIOS memory
23 storage medium
24 audio system
25 WLAN card
26 USB connector
31 embedded controller
32 input unit
33 power circuit
34 battery
120, 1506 connection layer
121 substrate
150, 151, 152, 153, 154 storage element
1500 first pad
1501 second pad
1502 first connection pad
1503 second connection pad
1504 first insulating layer
1505 second insulating layer

What is claimed is:

1. An electronic board comprising:
a support substrate;
a memory and a processor connected to the support substrate by solder; and
two or more storage elements that store an ID of the memory,
wherein each of the two or more storage elements has:
a first electrically conductive pad placed on the support substrate; and
a second electrically conductive pad placed on the support substrate, being spaced apart from the first pad by a gap, and
at least one of the two or more storage elements contains solder and has a connection layer that electrically connects the first pad and the second pad.

2. The electronic board according to claim 1, further comprising:
a first insulating layer placed on the first pad except a first area where the first pad and a part of the connection layer overlap; and
a second insulating layer placed on the second pad except a second area where the second pad and a part of the connection layer overlap.

3. The electronic board according to claim 2, wherein the first insulating layer and the second insulating layer are not placed in the gap.

4. The electronic board according to claim 1, wherein a width of the gap is 0.15 mm or more and 0.175 mm or less.
